(19) United States
(12) Patent Application Publication
(10) Pub. No.: US 2026/0185901 A1
(43) Pub. Date: Jul. 2, 2026

(54) ACTUATING DEVICE FOR A LAMBDA PROBE AND METHOD FOR COMPENSATING LEAKAGE CURRENTS

(71) Applicant: Robert Bosch GmbH, Stuttgart (DE)

(72) Inventors: Bernhard Ledermann, Weil Der Stadt (DE); Oemer Kaya, Sinsheim (DE)

(21) Appl. No.: 19/434,133

(22) Filed: Dec. 29, 2025

(30) Foreign Application Priority Data
Dec. 30, 2024 (DE) 10 2024 212 331.5

(51) Int. Cl. G01M 15/10; G01R 31/52

(52) U.S. Cl. CPC G01M 15/104; G01R 31/52

(57) ABSTRACT

The invention relates to a method for compensating for leakage currents (48, 50) of at least two connecting lines (18, 22, 100, 102) connecting a lambda probe (2, 78) to an actuating device (4,98), wherein the method comprises the following steps:
determining, for at least one of the connecting lines (18, 22, 100, 102), an associated leakage current (48, 50),
determining, for each detected leakage current (48, 50), whether the respective leakage current (48, 50) is a result-relevant leakage current (48) that affects the result of a lambda measurement performed by the lambda probe (2, 78), or not,
determining a compensation current, wherein only the leakage currents affecting the result (48) are taken into account in its determination.
applying the compensation current to at least one of the connecting lines (18, 22, 100, 102) of the lambda probe (2, 78).

### BACKGROUND

The invention relates to a method for compensating leakage currents. The invention also relates to an actuating device for a lambda probe and a device for detecting a lambda value. The invention also relates to an exhaust system of a motor vehicle and a motor vehicle.

Either application-specific integrated circuits, known as ASICS (Application Specific Integrated Circuits), or specific hardware modules with corresponding microcontrollers are used to operate lambda probes. The prior art for lambda probe evaluation circuits primarily comprises evaluation circuits specific to a particular probe type and hardware modules with microcontrollers. Both specific and generic ASICS are being developed for the newer generations of evaluation circuits. With previous control circuits, particularly in the case of jump probes, a particularly high degree of measurement accuracy was not required. However, with the introduction of newer exhaust emission regulations, such as EU7, the importance of measurement accuracy for such probes is coming into focus in order to improve exhaust emissions and thus comply with the new regulations.

The invention therefore aims to provide a method as well as an actuating device for a lambda probe that enable improved measurement accuracy when detecting the lambda value.

### SUMMARY

This task is solved by the method for compensating for leakage currents from at least two connecting lines according to the disclosure and an actuating device for a lambda probe according to the disclosure.

Further embodiments are specified in the dependent claims.

The invention relates to a method for compensating for leakage currents of at least two connecting lines connecting a lambda probe to an actuating device, wherein the method comprises the following steps:
determining, for at least one of the connecting lines, an associated leakage current,
determining, for each detected leakage current, whether the respective leakage current is a result-relevant leakage current that affects the result of a lambda measurement performed by the lambda probe, or not,
determining a compensation current, wherein only the leakage currents affecting the result are taken into account in its determination.
applying the compensation current to at least one of the connecting lines of the lambda probe.

The starting point for this method is the fact that different leakage currents have different effects on the result of the lambda measurement. When it comes to leakage currents occurring in the supply lines, a distinction can be made between leakage currents affecting the result of the lambda measurement and leakage currents that have little or no effect on the result. According to the embodiments of the invention, it is determined for each leakage current whether the leakage current is a leakage current affecting the result or a leakage current not affecting the result. Only the leakage currents affecting the result are then used to determine the compensation current. This produces a compensation current that can very accurately correct the change in the measurement result of the lambda probe caused by leakage currents.

The lambda probe can therefore determine correct lambda values even if there are leakage currents in the supply lines. The measurement errors caused by leakage currents can be eliminated or at least greatly reduced. This means that inexpensive insulation of the supply lines can also be tolerated. Compensating for the effects caused by leakage currents significantly improves the measurement accuracy of the lambda probe. This is particularly important in order to comply with the comparatively strict exhaust emission standards.

Furthermore, the invention relates to an actuating device for a lambda probe, which can be connected to the actuating device via at least two connecting lines, wherein the actuating device is designed to generate control signals for the lambda probe and to evaluate signals received from the lambda probe, wherein the actuating device comprises:
a compensation device designed for
determining an associated leakage current for at least one of the connecting lines,
determining, for each detected leakage current, whether the respective leakage current is a result-relevant leakage current that affects the result of a lambda measurement performed by the lambda probe, or not,
determining a compensation current, wherein only the leakage currents affecting the result are taken into account in its determination.
a controllable current source designed to additionally apply the compensation current to at least one of the connecting lines of the lambda probe.

The compensation current can be precisely specified using the adjustable current source. This compensation current is fed to at least one connection line of the lambda probe in order to eliminate or at least reduce the measurement errors caused by leakage currents. This increases the measurement accuracy.

The invention also relates to a device for detecting a lambda value, which comprises:
an actuating device as described above,
a lambda probe connected to the actuating device via at least two connecting lines.

Furthermore, the invention relates to an exhaust system for a motor vehicle, which comprises a device for detecting a lambda value as described above.

The invention also relates to a motor vehicle comprising an exhaust system with a device for detecting a lambda value as described above.

Preferably, those leakage currents that flow through the lambda probe are identified as leakage currents affecting the result.

According to a preferred embodiment of the invention, all leakage currents of the connecting lines affecting the result are taken into account when determining the compensation current.

Preferably, the method comprises the following further steps:
determining all leakage currents affecting the result,
determining the compensation current as the sum of all leakage currents affecting the result.

According to a preferred embodiment, the lambda probe is a jump probe comprising an inner pump electrode connection (IPE) and an outer pump electrode connection (APE), wherein an associated APE leakage current is determined for the outer pump electrode connection, and wherein the compensation current is equated to the APE leakage current.

Further preferably, the method comprises the further steps of:
determining an overall leakage current as the current difference between currents flowing from the actuating device to the lambda probe and currents flowing back from the lambda probe to the actuating device,
Determining the leakage currents of the connecting lines not affecting the result,
Determining the compensation current by subtracting the leakage currents not affecting the result from the overall leakage current.

It is advantageous if the lambda probe comprises an inner pump electrode connection and an outer pump electrode connection, wherein an associated IPE leakage current is determined for the inner pump electrode connection, and wherein the compensation current is determined by determining an overall leakage current as the current difference between currents flowing from the actuating device to the lambda probe and currents flowing back from the lambda probe to the actuating device, and subtracting the IPE leakage current from this overall leakage current. In this example, the IPE leakage current is the current contribution that does not affect the result.

Preferably, the compensation current is based on all leakage currents of the connecting lines affecting the result.

According to a preferred embodiment, the lambda probe is a jump probe or a single-cell broadband probe comprising a Nernst cell, wherein the leakage currents affecting the result are those leakage currents that flow through the Nernst cell.

Preferably, the lambda probe is a double-cell broadband probe comprising a Nernst cell and a pump cell, wherein the leakage currents affecting the result are those leakage currents flowing through the Nernst cell and/or the pump cell.

Preferably, the lambda probe comprises an inner pump electrode connection and an outer pump electrode connection, wherein an APE leakage current associated with the outer pump electrode connection affects the result and an IPE leakage current associated with the inner pump electrode connection does not affect the result.

### BRIEF DESCRIPTION OF THE DRAWINGS

Embodiments are explained in greater detail below with reference to the accompanying drawings. Shown are:

FIG. 1 a lambda probe designed as a jump probe together with an actuating device;

FIG. 2 an example of a leakage current affecting the result;

FIG. 3 an example of a leakage current not affecting the result;

FIG. 4 a compensation device implemented on the actuating device, which is designed to determine and compensate for a compensation current;

FIG. 5 an example of the implementation of an actuating device using an ASIC;

FIG. 6 the curve of the overall leakage current iDeltaAllPin and the Nernst voltage uNernst as a function of time; and

FIG. 7 a lambda probe designed as a broadband probe together with the associated actuating device.

### DETAILED DESCRIPTION

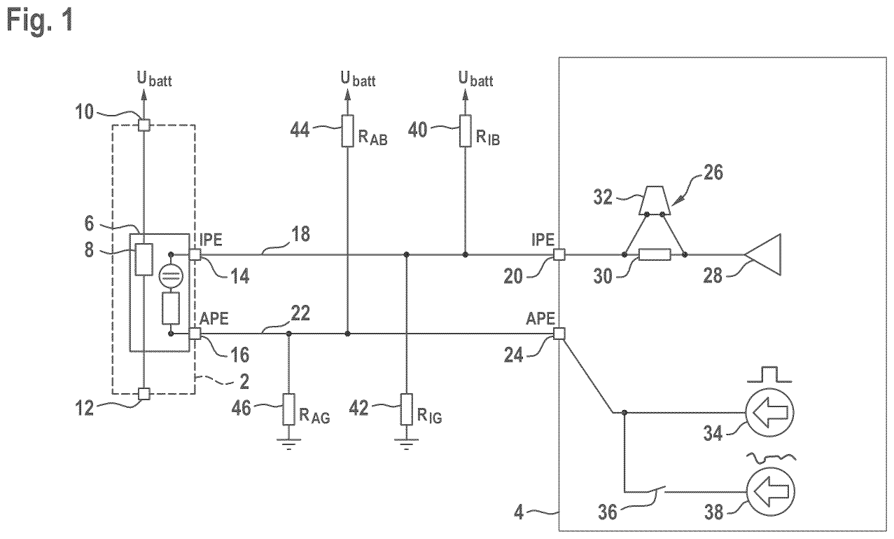

FIG. 1 shows a lambda probe 2 together with an associated actuating device 4, wherein the actuating device 4 may preferably be designed as part of an engine control unit (ECU). In the example shown in FIG. 1, the lambda probe 2 is designed as a simple jump probe comprising a Nernst cell 6. In order to heat the Nernst cell 6 to the intended operating temperature, the lambda probe 2 comprises a heating element 8 which is connected between a first operating voltage connection 10 and a second operating voltage connection 12. The Nernst voltage provided by the Nernst cell 6 can be tapped between an IPE connection 14 and an APE connection 16 of the lambda probe 2, wherein IPE denotes the inner pump electrode, and APE denotes the outer pump electrode of the lambda probe 2.

The IPE connection 14 of the lambda probe 2 is electrically connected to an IPE control connection 20 of the actuating device 4 via an IPE line 18. Similarly, the APE connection 16 of the lambda probe 2 is electrically connected to the APE control connection 24 of the actuating device 4 via an APE line 22. The IPE line 18 and the APE line 22 can preferably be designed as part of a cable or a cable harness.

In the actuating device 4, the IPE control connection 20 is connected to a reference potential 28 via a current measuring device 26. The reference potential 28 can be, for example, the grounding of the motor control unit or a virtual grounding. The abbreviation VG, which stands for virtual grounding, is used below for the virtual grounding. The current measuring device 26 is designed to measure the electrical current flowing back to the reference potential 28. For this purpose, the current measuring device 26 comprises a measuring resistor 30. The voltage drop across the measuring resistor 30 is converted by means of an analog-to-digital converter 32 into a digital value which indicates the current flowing back to the reference potential 28.

The APE control connection 24 of the actuating device 4 is connected to a pulsed current source 34 on the one hand and to a continuous current source 38 via a switch 36 on the other. An adjustable current can be supplied to the APE connection 16 of the lambda probe 2 via the APE line 22 using the two current sources 34 and 38. Preferably, the continuous current source 38 comprises a digital-to-analog converter which adjusts the current supplied to the APE connection 16 of the lambda probe 2 depending on a digitally preset value.

The lambda probe 2 is usually connected to four, five, or six individual wires, which may be connected to a cable or cable harness, for example. In the example shown in FIG. 1, the IPE line 18 and the APE line 22 are bundled together with the heating lines, for example, which are connected to the operating voltage connections 10 and 12 of the heating element 8. One of these heating lines is typically connected to the vehicle battery in order to provide the supply voltage for the heating element 8.

Like all electrical cables that are bundled together, probe lines also have a certain degree of electrical insulation. The insulation parameters of probe lines can vary depending on the manufacturer. Better insulation of the cables is usually associated with higher production costs, which is why manufacturers consider cost optimizations that can lead to poorer insulation of the probe lines. Poor insulation of the individual wires can be caused in particular by such cost savings, but also by manufacturing tolerances, wear and tear of the probe lines, and moisture in the lambda probe 2 and/or in the cable connections. The ohmic coupling between the probe lines affects the output signals of the lambda probe because the leakage currents through the insulation resistors of the probe lines impair the measuring accuracy of lambda probe 2. Under certain worst-case conditions, such as moisture or dew on the sensor connections and in the lambda probe, the insulation between the probe lines may deteriorate further, leading to a further deterioration in the measurement accuracy of the lambda probe.

The insulation resistors of the IPE line 18 and the APE line 22 are shown in FIG. 1. A first insulation resistor 40, labeled R_{IB}, indicates the resistance between the IPE line 18 and the battery voltage U_{batt.} A second insulation resistor 42, labeled R_{IG} in FIG. 1, indicates the resistance between the IPE line 18 and ground. A third insulation resistor 44, labeled R_{AB} indicates the resistance between the APE line 22 and the battery voltage U_{batt.} A fourth insulation resistor 46, labeled R_{AG} in FIG. 1, indicates the resistance between the APE line 22 and ground. The ohmic coupling between the probe lines caused by the insulation resistors 40 to 46 leads to the formation of leakage currents that impair the measurement accuracy of the lambda probe 2.

In order to comply with stricter exhaust gas regulations, the measurement accuracy of existing lambda probes can be improved either by using higher-quality cable insulation, which, however, involves higher costs, or by measuring and compensating for the leakage currents caused by the ohmic coupling between the cables, preferably using a software solution in combination with suitable hardware. This second approach, in which the leakage currents resulting from poor cable insulation are compensated by at least one compensation current, is described in more detail below.

First, it is necessary to determine the associated leakage current for each pin. The leakage currents can be measured, for example, at the beginning of a trip while the lambda probe is still cold, or alternatively at the end of a trip when the lambda probe has cooled down to a certain temperature. The measured values are stored in a non-volatile memory and can then be used for the next trip.

The following describes how the leakage currents (e.g., at APE or IPE) that occur during operation of the lambda probe can be distinguished. The easiest way is to measure a cold lambda probe, wherein a cold lambda probe is not conductive and has a very high resistance. To do this, the virtual grounding VG is first adjusted on the actuating device 4 side using an internal VG control system. Then, all pins are connected to each other to obtain a stable voltage. In the next step, all switch connections to the terminals are reopened and only the APE control connection 24 is connected to the virtual grounding VG.

As a result of this connection, a leakage current occurs in the event of an insulation problem in APE line 22. In the event of an insulation problem in IPE line 18, however, no leakage current occurs after a short settling time. The measured leakage current in this state is also referred to as iLeakAPE in the following.

Now all pins are connected to each other to obtain a stable voltage. In the next step, all switch connections to the terminals are reopened and only the IPE control connection 20 is connected to the virtual grounding VG.

As a result of this connection, a leakage current occurs in the event of an insulation problem in the IPE line 18. In the event of an insulation problem with APE line 22, however, no leakage current occurs after a short settling time. The measured leakage current in this state is also referred to as iLeakIPE in the following. The strength of this APE leakage current or IPE leakage current is measured by the current measuring device 26 and then stored.

More complex measurement methods and algorithms that do not necessarily require a cold sensor exist, for example, by measuring with and without a resistor connected in parallel and corresponding current measurements.

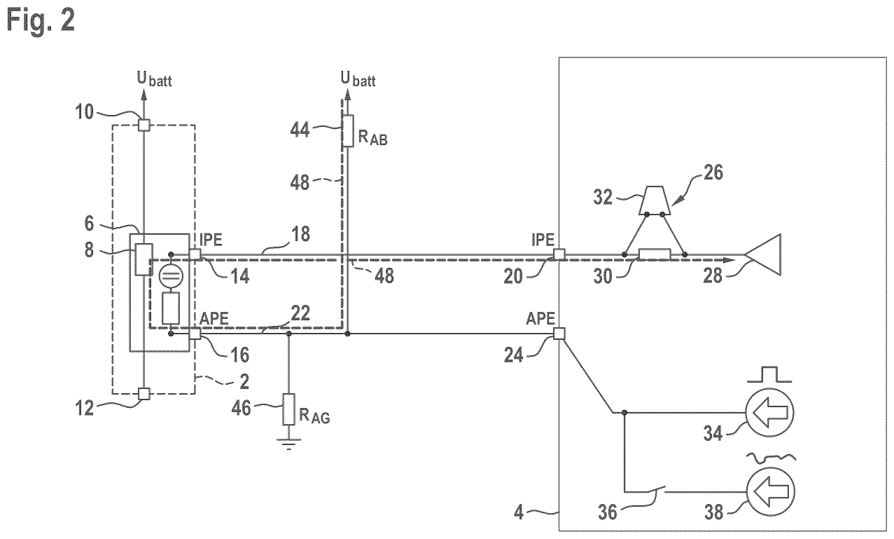

For each leakage current detected, it is determined whether the respective leakage current is a leakage current that affects the result of a lambda measurement performed by lambda probe 2, or not. First, the APE leakage current 48 shown in FIG. 2 is considered. The APE leakage current 48 flows through the Nernst cell 6 and will therefore influence the measurement of the Nernst voltage in either a positive or negative direction, resulting in a deviation of the measured lambda value from the actual lambda value.

In the case of poorly designed cable insulation, the APE leakage current 48 shown in FIG. 2 can have a significant effect on the measured values recorded by the lambda probe 2, as shown in the example below. If we assume that the battery voltage U_{batt}=12 V, the virtual ground VG=2 V, the resistance of the Nernst cell is 300 Ω and the third resistor 44 in the case of poor cable insulation R_{AB}=1 MΩ, then the APE leakage current 48 results in

$$iLeakAPE = ( 12 V - 2 V ) / 1 M Ω = 10 μA$$

This would change the Nernst voltage provided by the Nernst cell 6 by 3 mV. In the event of even poorer cable insulation with R_{AB}=100 kΩ, an APE leakage current 48 of 100 μA would result, which would lead to a deviation of 30 mV in terms of the Nernst voltage. The APE leakage current 48 is therefore a leakage current affecting the result. Compensating for this leakage current, which affects the results, could therefore significantly improve the measurement accuracy of lambda probe 2.

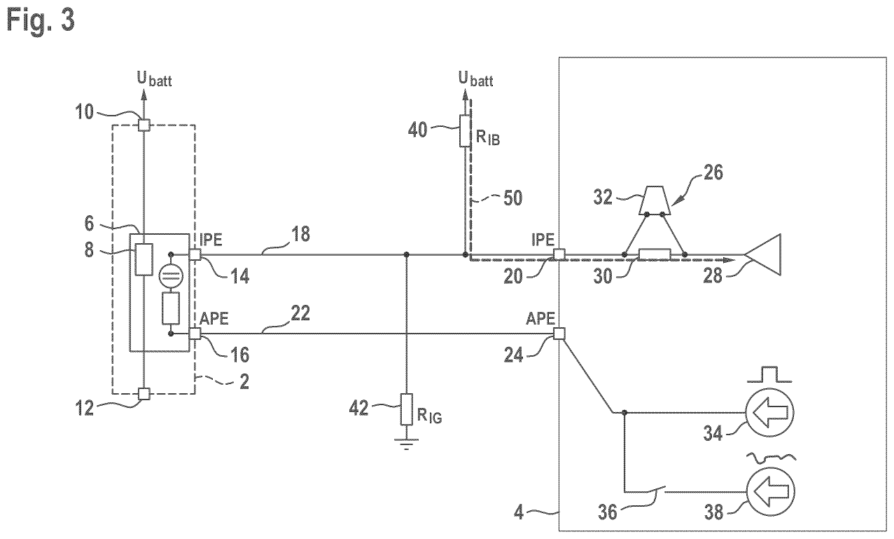

The situation is different with the IPE leakage current 50 shown in FIG. 3. The IPE leakage current 50 is a leakage current that does not affect the result because the IPE leakage current 50 flows directly via the IPE control connection 20 to the reference potential 28 without first flowing through the Nernst cell 6. Therefore, the IPE leakage current 50 has no influence on the Nernst voltage provided by the Nernst cell 6 and therefore has no effect on the lambda value measured by the lambda probe 2. The IPE leakage current 50 is therefore a leakage current not affecting the result. It is therefore not necessary to compensate for the IPE leakage current 50 in order to improve the measurement accuracy.

The following describes a method for determining the compensation current, wherein the compensation current only compensates for the leakage currents affecting the result, in this case the APE leakage current 48, while the leakage currents not affecting the result, in this case the IPE leakage current 50, are excluded from the determination of the compensation current and are not compensated. The following section describes the method for determining the compensation current for the example of a simple jump probe in more detail.

First, the total leakage current is determined, which is referred to below as iDeltaAllPin. The total leakage current iDeltaAllPin is the current difference between the current flowing from the actuating device 4 to the lambda probe 2, referred to as iSet, and the current flowing back from the lambda probe 2 to the actuating device 4, referred to below as iRefR. This results in the following for the overall leakage current

$$iDeltaAllPin = iSet - iRefR$$

After no continuous current is set at the continuous current source 38, iSet=0. If a value of iDeltaAllPin>0 or iDeltaAllPin<0 results, this indicates that leakage currents are occurring. In this case, the compensation procedure is activated. A value of iDeltaAllPin<0 indicates a weak leakage current in the direction of the battery in this configuration of the actuating device 4, whereas a value of iDeltaAllPin>0 indicates a leakage current to grounding.

Based on the overall leakage current iDeltaAllPin, the next step is to determine the compensation current, which is referred to below as iShuntCorr. It should be noted here that the overall leakage current iDeltaAllPin comprises both leakage currents affecting the result and leakage currents not affecting the result. The leakage currents not affecting the result do not contribute to the measurement error of the lambda value, but are included in the overall leakage current iDeltaAllPin. Therefore, the leakage currents not affecting the result must be subtracted from the overall leakage current iDeltaAllPin. To determine the compensation current iShuntCorr, all leakage currents not affecting the result are subtracted from the overall leakage current iDeltaAllPin. In this case, the leakage current iLeakIPE, which does not affect the result, is subtracted from the total leakage current iDeltaAllPin. The compensation current iShuntCorr is therefore calculated as follows:

$$iShuntCorr = iDeltaAllPin - iLeakAPE$$

The value of the compensation current iShuntCorr determined in this way is fed to the digital-to-analog converter of the continuous current source 38. This sets the continuous current source 38 so that it supplies the lambda probe 2 with the required compensation current iShuntCorr via the APE control connection 24, the APE line 22, and the APE connection 16. By applying this compensation current, the measurement error caused by the leakage currents affecting the results can be prevented or at least reduced.

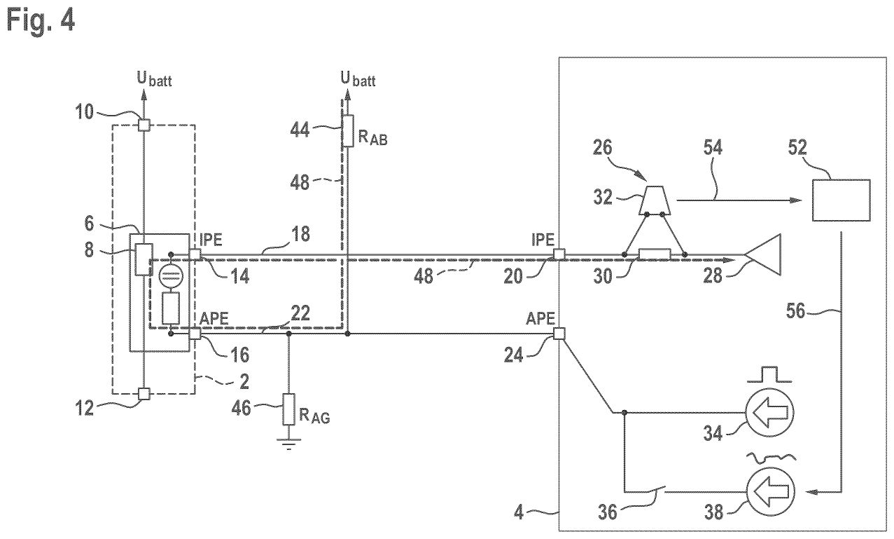

FIG. 4 shows the lambda probe 2 and the actuating device 4 again, wherein the actuating device 4 comprises a compensation device 52 that is designed to perform the compensation method described above. The compensation device 52 can preferably be designed as a software-implemented compensation device. For example, the value of the return current iRefR and the previously measured amplitudes of the leakage currents can be supplied to the compensation device 52 as input variables 54. Based on these input variables 54, the compensation device 52 determines the value of the required compensation current iShuntCorr. The determined value iShuntCorr is fed to the digital-to-analog converter of the controllable current source 38 in accordance with arrow 56.

The advantage of the solution described here is that the effects of weak leakage currents caused by insulation resistors can be prevented or reduced. This is achieved by using a current measuring device 26 for the return current that is as precise as possible and capable of determining the current amplitudes with a high degree of accuracy. This is further achieved by a flexible switching arrangement for determining the various leakage currents in order to be able to determine leakage currents affecting the result and those not affecting the result, as well as by means of a preferably software-based method for determining the deviation between the currents flowing to the lambda probe and those flowing back from the lambda probe, and for deriving the leakage currents affecting the result from this. This is further achieved by a precise current source that supplies the lambda probe with additional current (positive or negative) and compensates for the leakage currents affecting the results, thereby eliminating or at least reducing the effects of the leakage currents.

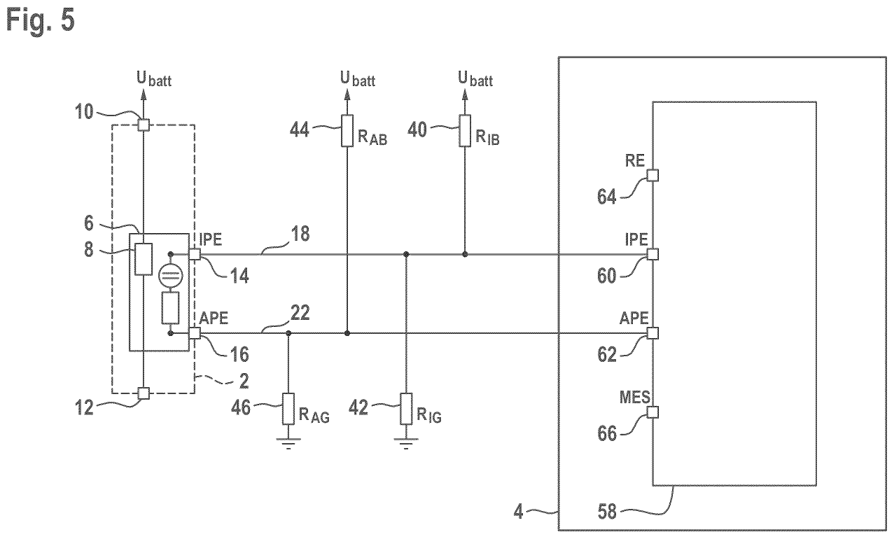

It is particularly advantageous to implement some or all of the components of the actuating device 4 on an application-specific integrated circuit (ASIC). FIG. 5 shows one such embodiment in which the components of the actuating device 4 described above are housed on an ASIC 58. The ASIC 58 has an IPE control connection 60 and an APE control connection 62. In addition, the ASIC 58 has a RE connection 64 and a MES connection 66. The RE port 64 (reference electrode port) and the MES connection 66 are additional ASIC connections specifically for operating broadband probes. The IPE control connection 60 is connected to the IPE connection 14 of the lambda probe 2 via the IPE line 18, and the APE control connection 62 is connected to the APE connection 16 of the lambda probe 2 via the APE line 22. Precise current sources and current measuring devices in particular can be provided on the ASIC 58.

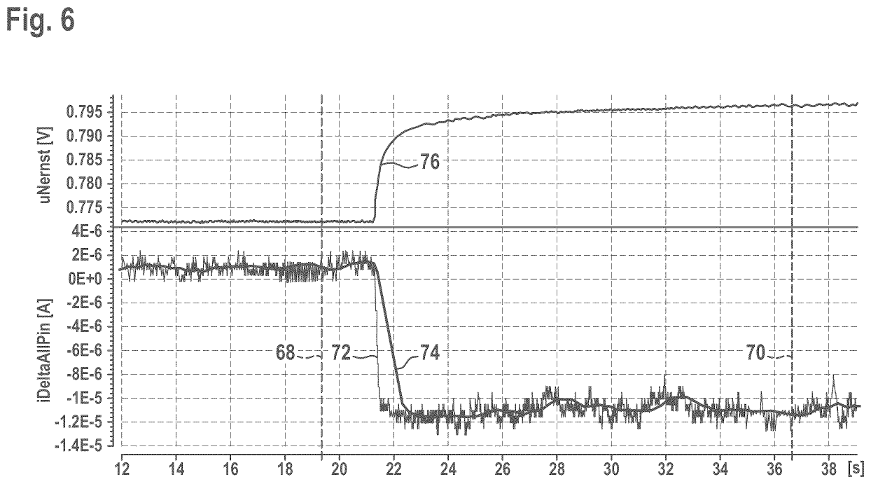

FIG. 6 shows an example measurement performed on a lambda probe 2, wherein the APE connection 16 of the lambda probe 2 is connected to the battery voltage Ubatt at a specific point in time via a high-impedance resistor of 1 MW·Ω FIG. 6 shows both the overall leakage current iDeltaAllPin and the Nernst voltage uNernst as a function of time. The first dashed line 68 marks a point in time before the shunt connection, while the second dashed line 70 marks a point in time after the shunt connection has been made. Based on the temporal progression of the overall leakage current iDeltaAllPin, which is plotted in the lower region of FIG. 6 as a fluctuating current curve 72 and as a smoothed current profile 74 it can be seen that the overall leakage current is approximately 1 μA before the shunt connection and approximately −11 μA after the shunt connection, so that the total leakage current changes by approximately 12 μA. A rough estimate of the leakage current confirms this order of magnitude:

$$iShunt = ( {U}_{batt} - {U}_{VG} ) / RShunt = ( 14 V - 2.2 V ) / 1000000 Ω = 11.8 μA$$

The effect of the shunt connection is also directly recognizable in the time curve 76 of the Nernst voltage plotted in the upper section of FIG. 6. The Nernst voltage rises from the initial value of 0.772 V to 0.797 V as a result of the shunt connection, which corresponds to a voltage change of approximately 25 mV. This increase in Nernst voltage is therefore due to the additional leakage current in the direction of the battery voltage U_{batt}.

According to the procedure described above, by applying a suitable compensation current, the increase in the Nernst voltage uNernst shown in FIG. 6, which is caused by the additional leakage current in the direction of the battery voltage U_{batt}, can be avoided, so that a constant Nernst voltage is maintained regardless of the leakage currents.

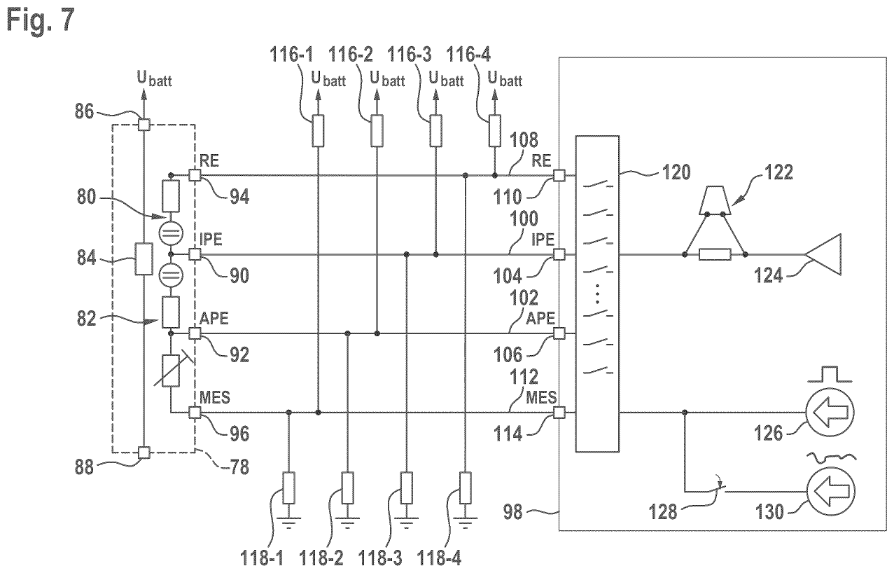

The procedure described above for compensating leakage currents can also be applied to broadband lambda probes. FIG. 7 shows a broadband lambda probe 78 comprising a Nernst cell 80 and a pump cell 82. In addition, the broadband lambda probe 78 has a heating element 84 connected between a first operating voltage connection 86 and a second operating voltage connection 88. The broadband lambda probe 78 has an IPE connection 90, an APE connection 92, an RE connection 94 and an MES connection 96. The broadband lambda probe 78 is actuated by an actuating device 98. For this purpose, the IPE connection 90 and the APE connection 92 are connected via an IPE line 100 and an APE line 102 to the IPE control connection 104 and the APE control connection 106 of the actuating device 98. The RE connection 94 is connected to the RE control connection 110 of the actuating device 98 via an RE line 108, and the MES connection 96 is connected to the MES control connection 114 of the actuating device 98 via an MES line 112. Each of the lines 100, 102, 108, 112 is connected to Ubatt via one of the insulation resistors 116-1 to 116-4 and to grounding via one of the insulation resistors 118-1 to 118-4.

The actuating device 98 has a switching arrangement 120. Via this switching arrangement 120, each of the lines 100, 102, 108, 112 can be connected to the current measuring device 122 and the reference potential 124. In addition, it is possible to connect each of the lines 100, 102, 108, 112 to a pulsed current source 126 and/or to a continuous current source 130 via a switch 128 using the switching arrangement 120. Thanks to these switching options, the different leakage currents can be measured individually one after the other or determined retrospectively on the basis of a plurality of measurements.

The determination of the compensation current for a broadband lambda probe works essentially in the same way as the method described above for a jump probe. Given the larger number of pins, additional measurements are required for the additional pins in order to determine the leakage currents, but the basic principle is the same as for the jump probe: First, the leakage currents are measured, then the leakage currents affecting the result are determined, and then the leakage currents affecting the result are compensated by appropriately controlling a current source.

The procedure for the broadband lambda probe is described in more detail below. First, the overall leakage current iDeltaAllPin is determined using the equation

$$iDeltaAllPin = iSet - iRefR ,$$

wherein iSet denotes the current flowing to the lambda probe and iRefR denotes the current flowing back. Unlike a jump probe, iSet can take on any value in a broadband lambda probe. iDeltaAllPin<0 indicates a weak leakage current to the battery, while iDeltaAllPin>0 indicates a weak leakage current to grounding. The overall leakage current iDeltaAllPin contains both leakage currents affecting the result and leakage currents not affecting the result. In this respect, in order to determine the compensation current iShuntCorr, it is necessary to subtract the leakage currents not affecting the result from the total leakage current, so that the compensation current iShuntCorr is given by:

$$iShuntCorr = iDeltaAllPin - iLeakAPE$$

The compensation current iShuntCorr is then added to the input value of the digital-to-analog converter of the continuous current source 130 in order to compensate for the leakage current by the value iShuntCorr.

The features disclosed in the foregoing description, claims and drawings may be of importance, both individually and in any combination, for the realization of the invention in its various embodiments.

1. A method for compensating for leakage currents of at least two connecting lines connecting a lambda probe to an actuating device, wherein the method comprises:
determining, for at least one of the connecting lines, an associated leakage current,
determining, for each detected leakage current, whether the respective leakage current is a result-relevant leakage current that affects a result of a lambda measurement performed by the lambda probe, and
determining a compensation current, wherein only the leakage currents affecting the result (48) are taken into account in its determination,
applying the compensation current to at least one of the connecting lines of the lambda probe.

2. The method according to claim 1, wherein those leakage currents that flow through the lambda probe are identified as leakage currents affecting the result.

3. The method according to claim 1, wherein, when determining the compensation current, all leakage currents affecting the result of the connecting lines are taken into account.

4. The method according to claim 1, further comprising:
determining all leakage currents affecting the result,
determining the compensation current as a sum of all leakage currents affecting the result.

5. The method according to claim 1, wherein the lambda probe is a jump probe which comprises an inner pump electrode connection and an outer pump electrode connection, wherein an associated APE leakage current is determined for the outer pump electrode connection, and wherein the compensation current is equated with the APE leakage current.

6. The method according to claim 1, further comprising:
determining an overall leakage current as a current difference between currents flowing from the actuating device to the lambda probe and currents flowing back from the lambda probe to the actuating device,
determining the leakage currents not affecting the result of the connecting lines,
determining the compensation current by subtracting the leakage currents not affecting the result from the overall leakage current.

7. The method according to claim 1, wherein the lambda probe comprises an inner pump electrode connection and an outer pump electrode connection, wherein an associated IPE leakage current is determined for the inner pump electrode connection, and wherein the compensation current is determined by calculating an overall leakage current as a current difference between the currents flowing from the actuating device to the lambda probe and the currents flowing back from the lambda probe to the actuating device, and the IPE leakage current is subtracted from this overall leakage current.

8. An actuating device for a lambda probe, configured to be connected to the actuating device via at least two connecting lines, wherein the actuating device is configured to generate control signals for the lambda probe and to evaluate signals received from the lambda probe, wherein the actuating device comprises:
a compensation device configured to
determine an associated leakage current for at least one of the connecting lines,
determine, for each detected leakage current, whether the respective leakage current is a result-relevant leakage current that affects a result of a lambda measurement performed by the lambda probe, and
determine a compensation current, wherein only the leakage currents affecting the result are taken into account in its determination,
a controllable current source configured to additionally apply the compensation current to at least one of the connecting lines of the lambda probe.

9. An actuating device according to claim 8, wherein the compensation current is based on all leakage currents affecting the result of the connecting lines.

10. A device for detecting a lambda value, which has:
an actuating device according to claim 8, and
a lambda probe connected to the actuating device via at least two connecting lines.

11. The device according to claim 10, wherein the lambda probe is a jump probe or a single-cell broadband probe comprising a Nernst cell, and in that the leakage currents affecting the result are those leakage currents that flow through the Nernst cell.

12. The device according to claim 10, wherein the lambda probe is a double-cell broadband probe comprising a Nernst cell and a pump cell, and that the leakage currents affecting the result are those leakage currents that flow through the Nernst cell and/or the pump cell.

13. The device according to claim 10, wherein the lambda probe comprises an inner pump electrode connection and an outer pump electrode connection, wherein an APE leakage current associated with the outer pump electrode connection affects the result and an IPE leakage current associated with the inner pump electrode connection does not affect the result.

14. An exhaust system for a motor vehicle, comprising a device for detecting a lambda value according to claim 10.

15. A motor vehicle comprising an exhaust system with a device for detecting a lambda value according to claim 10.
